(19) United States
(12) Patent Application Publication
(10) Pub. No.: US 2021/0141564 A1
(43) Pub. Date: May 13, 2021

(54) MEMORY CONTROLLER, MEMORY SYSTEM HAVING MEMORY CONTROLLER, AND METHOD OF OPERATING MEMORY CONTROLLER

(71) Applicant: SK hynix Inc., Gyeonggi-do (KR)

(72) Inventor: Seung Hwan SHIN, Gyeonggi-do (KR)

(21) Appl. No.: 16/875,667

(22) Filed: May 15, 2020

(30) Foreign Application Priority Data
Nov. 7, 2019 (KR) 10-2019-0141735

(51) Int. Cl. G06F 3/06

(52) U.S. Cl. CPC G06F 3/0659; G06F 3/0673; G06F 3/0653; G06F 3/0604

(57) ABSTRACT

Provided herein may be a memory controller, a memory system having the memory controller, and a method of operating the memory controller. The memory controller may include a central processing unit configured to generate a command set that includes a command and an address for controlling an operation of a memory device, a temperature information generator configured to generate temperature information based on a temperature sensing value, and a memory interface configured to generate an expanded command set by including the temperature information in the command set, and transmit the expanded command set to the memory device.

### CROSS-REFERENCE TO RELATED APPLICATION

The present application claims priority under 35 U.S.C. § 119(a) to Korean patent application number 10-2019-0141735, filed on Nov. 7, 2019, which is incorporated herein by reference in its entirety.

### BACKGROUND

### 1. Field of Invention

Various embodiments of the present disclosure relate to a memory controller, a memory system having the memory controller, and a method of operating the memory controller. More particularly, embodiments of the present disclosure relate to a memory controller that is capable of performing temperature compensation, a memory system having the memory controller, and a method of operating the memory controller.

### 2. Description of Related Art

A memory system may include a memory device and a memory controller.

The memory controller may control the operation of the memory system in response to a request received from a host. The memory device may store data or output stored data under the control of the memory controller. For example, the memory device may be implemented as a volatile memory device in which stored data is lost when the supply of power is interrupted or as a nonvolatile memory device in which stored data is retained even when the supply of power is interrupted.

### SUMMARY

Various embodiments of the present disclosure are directed to a memory controller, which can transmit temperature information to a memory device, a memory system having the memory controller, and a method of operating the memory controller.

An embodiment of the present disclosure may provide for a memory controller. The memory controller may include a central processing unit configured to generate a command set that includes a command and an address for controlling an operation of a memory device; a temperature information generator configured to generate temperature information based on a temperature sensing value, and a memory interface configured to generate an expanded command set by including the temperature information in the command set, and transmit the expanded command set to the memory device.

An embodiment of the present disclosure may provide for a memory system. The memory system may include a memory controller configured to generate an expanded command set including a command, an address, and temperature information; and a memory device configured to receive the expanded command set from the memory controller, perform an operation in response to the command and the address in the expanded command set, and determine operating voltages to be used for the operation based on the temperature information in the expanded command set.

An embodiment of the present disclosure may provide for a method of operating a memory controller. The method may include generating a command set that includes a command and an address for controlling an operation of a memory device, generating temperature information based on a temperature sensing value, generating an expanded command set by including the temperature information into the command set, and transmitting the generated expanded command set to the memory device.

An embodiment of the present disclosure may provide for a memory controller. The memory controller may include a temperature information generator configured to compare a first temperature corresponding to a first temperature sensing value with a second temperature corresponding to a second temperature sensing value, and to output a first signal when a difference between the first temperature and the second temperature is equal to or greater than a first threshold value, and a central processing unit configured to perform a set operation when the first signal is received from the temperature information generator, wherein the first temperature sensing value is indicative of temperature inside the memory controller, and the second temperature sensing value is indicative of temperature outside the memory controller.

An embodiment of the present disclosure may provide for a method of operating a memory system. The method may include sensing, by the controller, a temperature of the memory device, providing the memory device with temperature information representing the sensed temperature, and performing, by the memory device, an operation by adjusting an operation voltage according to the temperature information.

### BRIEF DESCRIPTION OF THE DRAWINGS

FIG. 1 is a diagram illustrating an exemplary memory system.

FIG. 2 is a diagram explaining threshold voltage distributions of memory cells.

FIG. 3 is a diagram illustrating an example of a memory controller illustrated in FIG. 1.

FIG. 4 is a diagram illustrating another example of a memory controller illustrated in FIG. 1.

FIG. 5 is a diagram illustrating an exemplary memory interface illustrated in FIGS. 3 and 4.

FIGS. 6 and 7 are diagrams explaining an example of generating temperature information.

FIG. 8 is a flowchart illustrating a method of operating a memory controller according to an embodiment of the present disclosure.

FIG. 9 is a diagram illustrating an exemplary memory controller illustrated in FIG. 1.

FIG. 10 is a diagram illustrating a memory device according to an embodiment of the present disclosure.

FIG. 11 is a diagram explaining a table in which operating voltages are mapped to corresponding pieces of temperature information.

FIG. 12 is a diagram illustrating an exemplary memory block.

FIG. 13 is a diagram illustrating an embodiment of a memory system including the memory controller illustrated in FIGS. 3, 4, and/or 9.

FIG. 14 is a diagram illustrating an embodiment of a memory system including the memory controller illustrated in FIGS. 3, 4, and/or 9.

FIG. 15 is a diagram illustrating an embodiment of a memory system including the memory controller illustrated in FIGS. 3, 4, and/or 9.

FIG. 16 is a diagram illustrating an embodiment of a memory system including the memory controller illustrated in FIGS. 3, 4, and/or 9.

### DETAILED DESCRIPTION

The following description, with reference to the accompanying drawings, is directed to illustrating and describing various embodiments of the present invention. However, the present invention may be embodied in other forms, which may be variations of any of the disclosed embodiments. Thus, the present invention is not limited to or by any of the disclosed embodiments or any specific details.

Throughout the specification, reference to “an embodiment” or the like is not necessarily to only one embodiment, and different references to any such phrase are not necessarily to the same embodiment(s). Also, an open-ended transition term, such as “comprising,” “including” or the like, when used herein, does not preclude the existence or addition of one or more elements or operations in addition to those stated. Similarly, use of an indefinite article, i.e., “a” or “an,” is intended to mean one or more, unless the context clearly indicates that only one is intended.

FIG. 1 is a diagram illustrating an exemplary memory system.

A memory system 2000 may include at least one memory device 2200 which stores data, and a memory controller 2100 which controls the memory device(s) 2200 in response to a request received from a host 1000.

The host 1000 may be a device or a system which stores data in the memory system 2000 or retrieves data from the memory system 2000. For example, the host 1000 may be any of a computer, a portable digital device, a tablet, a digital camera, a digital audio player, a television, a wireless communication device, and a cellular phone, but embodiments of the present disclosure are not limited thereto.

The memory controller 2100 may control the overall operation of the memory system 2000. The memory controller 2100 may perform various operations in response to requests received from the host 1000. For example, the memory controller 2100 may perform any of various operations including a program operation, a read operation, and/or an erase operation on the memory device 2200.

The memory controller 2100 may generate a command set so as to control the operation of the memory device 2200. The command set may include a command and an address.

In an embodiment, the memory controller 2100 may generate an expanded command set by inserting temperature information into the command set, and may then transmit the expanded command set to the memory device 2200. For example, during a program operation, the memory controller 2100 may transmit the expanded command set and data to the memory device 2200. For example, during a read operation or an erase operation, the memory controller 2100 may transmit the expanded command set to the memory device 2200.

In an embodiment, the temperature information may indicate either the temperature of the memory controller 2100 or include an index indicating a temperature interval to which the temperature of the memory controller 2100 belongs, among a plurality of set temperature intervals. The temperature of the memory controller 2100 may be, for example, temperature measured inside the memory controller 2100 or temperature measured at a location near the memory controller 2100. For example, the memory controller 2100 may be implemented as one or more chips. In the case of a single chip implementation, the temperature of the memory controller 2100 may be temperature measured inside the chip in which the memory controller 2100 is implemented, or temperature measured on the outer surface of the chip in which the memory controller 2100 is implemented. In the case of a multi-chip implementation, the temperature of the memory controller 2100 may be measured on the substrate on which the chips are mounted.

In an embodiment, the temperature information may indicate either the temperature of the memory system 2000 or an index indicating a temperature interval to which the temperature of the memory system 2000 belongs, among a plurality of set temperature intervals. The temperature of the memory system 2000 may be, for example, temperature measured inside the memory system 2000. For example, each of the memory controller 2100 and the memory device 2200 may be implemented as one or more chips. The temperature of the memory system 2000 may be temperature measured on a substrate on which the chips are mounted.

The memory device 2200 may perform a program operation, a read operation, and/or an erase operation under the control of the memory controller 2100. For example, during a program operation, the memory device 2200 may receive the expanded command set and data from the memory controller 2100, and may store the data based on the received expanded command set. For example, during a read operation, the memory device 2200 may receive the expanded command set from the memory controller 2100, and may perform a read operation based on the received expanded command set. For example, during an erase operation, the memory device 2200 may receive the expanded command set from the memory controller 2100, and may perform an erase operation based on the received expanded command set.

In an embodiment, the memory device 2200 may determine operating voltages based on the temperature information included in the expanded command set, and may perform the corresponding operation in response to the command and the address included in the expanded command set using the determined operating voltages. For example, the memory device 2200 may determine or change a program start voltage, a program verify voltage, a program step voltage, a read voltage, an erase voltage, and/or a pass voltage based on the temperature information.

The memory device 2200 may be implemented as a volatile memory device in which stored data is lost when the supply of power is interrupted or as a nonvolatile memory device in which stored data is retained even when the supply of power is interrupted.

The memory device 2200 may include at least one storage area in which data is stored. The storage area may correspond to one page including a plurality of memory cells, one memory block including a plurality of pages, or one plane including a plurality of memory blocks, but embodiments of the present disclosure are not limited thereto.

The memory cells may be driven using a single-level cell (SLC) method or an m-bit multi-level cell (MLC) method. Each of memory cells driven using the SLC method may store 1-bit data, and each of memory cells driven using the m-bit MLC method may store m-bit data. Here, m may be a natural number of 2 or more.

FIG. 2 is a diagram explaining threshold voltage distributions of memory cells.

Although threshold voltage distributions of memory cells driven using a 2-bit MLC method are illustrated in FIG. 2 by way of example, embodiments of the present disclosure are not limited thereto. In FIG. 2, a horizontal axis indicates threshold voltages Vth of memory cells, and a vertical axis indicates the number of memory cells (#cells) corresponding to each threshold voltage Vth.

In a 2-bit MLC method, when a program voltage is applied to a selected word line coupled to selected memory cells after a program permission voltage or a program inhibition voltage has been applied to bit lines, each memory cell may be programmed to have a threshold voltage corresponding to an erased state E0, a first program state P1, a second program state P2 or a third program state P3. Here, a pass voltage may be applied to unselected word lines.

After the program voltage has been applied to the selected word line, a program verify operation of verifying whether the selected memory cells have been programmed to desired program states may be performed. During the program verify operation, a first program verify voltage Vvf1, a second program verify voltage Vvf2 or a third program verify voltage Vvf3 may be applied to the selected word line. Here, the pass voltage may be applied to unselected word lines. The first program verify voltage Vvf1 may be used to verify whether the selected memory cells have been programmed to the first program state P1, the second program verify voltage Vvf2 may be used to verify whether the selected memory cells have been programmed to the second program state P2, and the third program verify voltage Vvf3 may be used to verify whether the selected memory cells have been programmed to the third program state P3.

When the program verify operation is performed using the first program verify voltage Vvf1, memory cells having threshold voltages lower than the first program verify voltage Vvf1 may be determined to be on cells, and memory cells having threshold voltages higher than the first program verify voltage Vvf1 may be determined to be off cells. When the program verify operation is performed using the second program verify voltage Vvf2, memory cells having threshold voltages lower than the second program verify voltage Vvf2 may be determined to be on cells, and memory cells having threshold voltages higher than the second program verify voltage Vvf2 may be determined to be off cells. When the program verify operation is performed using the third program verify voltage Vvf3, memory cells having threshold voltages lower than the third program verify voltage Vvf3 may be determined to be on cells, and memory cells having threshold voltages higher than the third program verify voltage Vvf3 may be determined to be off cells.

When a read operation is performed on memory cells programmed using the 2-bit MLC method, a first read voltage Vrd1, a second read voltage Vrd2 or a third read voltage Vrd3 may be applied to a selected word line. Here, the pass voltage may be applied to unselected word lines. The first read voltage Vrd1 may be set between a threshold voltage distribution corresponding to the erased state E0 and a threshold voltage distribution corresponding to the first program state P1. The second read voltage Vrd2 may be set between the threshold voltage distribution corresponding to the first program state P1 and a threshold voltage distribution corresponding to the second program state P2. The third read voltage Vrd3 may be set between the threshold voltage distribution corresponding to the second program state P2 and a threshold voltage distribution corresponding to the third program state P3.

The memory cells in the erased state E0 may be determined to be on cells when the first read voltage Vrd1 is applied to the selected word line. The memory cells in the first program state P1 may be determined to be off cells when the first read voltage Vrd1 is applied to the selected word line, and may be determined to be on cells when the second read voltage Vrd2 is applied to the selected word line. The memory cells in the second program state P2 may be determined to be off cells when the second read voltage Vrd2 is applied to the selected word line, and may be determined to be on cells when the third read voltage Vrd3 is applied to the selected word line. The memory cells in the third program state P3 may be determined to be off cells when the third read voltage Vrd3 is applied to the selected word line.

Although the same program voltage is applied to the selected word line during a program operation, the number of electrons that are stored or trapped in each memory cell may change with temperature, and current flowing through the corresponding memory cell (cell current) may change with temperature during a program verify operation and a read operation. For example, as temperature falls, the resistance of a conductor or a semiconductor may decrease, and thus cell current may increase. In contrast, as temperature rises, the resistance of a conductor or a semiconductor may increase, and thus cell current may decrease. Therefore, the memory cells may not be programmed to have desired voltage levels during a program operation, or data in the memory cells may be erroneously sensed during a program verify or read operation. Similarly, the memory cells may not be erased to desired voltage levels or lower during an erase operation.

Therefore, in order to compensate for temperature change, there is a need to set operating voltages to be used in respective operations depending on temperature during a program operation, a read operation or an erase operation.

FIG. 3 is a diagram illustrating an example of the memory controller illustrated in FIG. 1.

The memory controller 2100 may include a host interface 2110, a temperature sensor 2120a, a temperature information generator 2130, a memory interface 2140, a central processing unit (CPU) 2150, an error correction circuit 2160, and a buffer memory 2170. The host interface 2110, the temperature information generator 2130, the memory interface 2140, the error correction circuit 2160, and the buffer memory 2170 may be controlled by the central processing unit 2150.

The host interface 2110 may communicate with a host 1000 using various interface protocols. For example, the host interface 2110 may communicate with the host 1000 using at least one of interface protocols, such as Non-Volatile Memory express (NVMe), Peripheral Component Interconnect-Express (PCI-E), Advanced Technology Attachment (ATA), Serial ATA (SATA), Parallel ATA (PATA), Universal Serial Bus (USB), Multi-Media Card (MMC), Enhanced Small Disk Interface (ESDI), Integrated Drive Electronics (IDE), Mobile Industry Processor Interface (MIPI), Universal Flash Storage (UFS), Small Computer System Interface (SCSI), and serial attached SCSI (SAS), but embodiments of the present disclosure are not limited thereto.

The temperature sensor 2120a may sense the temperature of the memory controller 2100, and may provide a temperature sensing value St1 to the temperature information generator 2130. For example, a thermocouple, a resistance temperature detector (RTD) or a thermistor may be used as the temperature sensor 2120a, but embodiments of the present disclosure are not limited thereto. The temperature sensing value St1 may be an analog signal varying with temperature, and may be, for example, a voltage value or a resistance value. The temperature sensor 2120a may continuously or periodically provide the temperature sensing value St1 to the temperature information generator 2130.

The memory controller 2100 may be implemented as at least one chip, and the temperature sensor 2120a may be located inside the chip in which the memory controller 2100 is implemented, or located on the outer surface of the chip in which the memory controller 2100 is implemented.

The temperature information generator 2130 may convert the temperature sensing value St1 received from the temperature sensor 2120a into temperature information represented by a digital code, and may provide the temperature information to the memory interface 2140.

In an embodiment, the temperature information generator 2130 may include a first table in which temperatures are mapped to respective temperature sensing values corresponding thereto. For example, when the temperature sensing value St1 is received from the temperature sensor 2120a, the temperature information generator 2130 may identify the temperature corresponding to the temperature sensing value St1 with reference to the first table, and may provide the identified temperature as the temperature information.

In an embodiment, the temperature information may be an index indicating a temperature interval to which temperature corresponding to the temperature sensing value belongs, among a plurality of set temperature intervals. The index may be represented by digital code. For example, the temperature information generator 2130 may include a second table in which indices indicate respective temperature intervals. When the temperature sensing value St1 is received from the temperature sensor 2120a, the temperature information generator 2130 may identify an index indicating a temperature interval corresponding to the temperature sensing value St1 with reference to the second table, and may provide the identified index as the temperature information.

In an embodiment, the temperature information generator 2130 may periodically generate and update temperature information based on the temperature sensing value St1 received from the temperature sensor 2120a. As the resolution of the temperature information becomes higher, temperature information composed of a larger number of bits may be generated. Thus, the size and configuration of the first table or the second table may change depending on the resolution of the temperature sensed by the temperature sensor 2120a.

In an embodiment, the temperature information generator 2130 may provide the temperature information to the memory interface 2140 when a request is received from the central processing unit 2150.

The memory interface 2140 may generate an expanded command set by inserting the temperature information received from the temperature information generator 2130 into a command set received from the central processing unit 2150, and may transmit the generated expanded command set to the memory device 2200.

In an embodiment, the memory interface 2140 may transmit a command, an address, and the temperature information included in the expanded command set to the memory device 2200 in a determined order.

The central processing unit 2150 may perform various types of calculations (operations) or generate the command set so as to control the memory device 2200. The command set may include a command and an address. For example, the central processing unit 2150 may generate a command set required for a program operation, a read operation or an erase operation in response to a request received from the host 1000, and may transmit the generated command set to the memory interface 2140. Here, the central processing unit 2150 may request the temperature information generator 2130 to generate temperature information and to transmit the temperature information to the memory interface 2140.

The central processing unit 2150 may translate a logical address contained in the request received from the host 1000 into a physical address so as to control the operation of the memory device 2200. The central processing unit 2150 may translate a logical address into a physical address or translate a physical address into a logical address with reference to an address mapping table stored in the buffer memory 2170. The central processing unit 2150 may update the address mapping table when new data is programmed to the memory device 2200 or when data stored in the memory device 2200 is erased.

The error correction circuit 2160 may perform error correction encoding on data to be programmed to the memory device 2200, and may perform error correction decoding on read data received from the memory device 2200. The error correction circuit 2160 may have a maximum error correction capability. For example, when a number of error bits in the read data do not exceed the maximum error correction capability are present, the error correction circuit 2160 may detect and correct the error included in the read data. The maximum error correction capability may correspond to a maximum allowable number of error bits that are correctable by the error correction circuit 2160. When a number of error bits in the read data exceed the maximum allowable number of error bits, error correction decoding may fail.

The buffer memory 2170 may temporarily store data while the memory controller 2100 controls the memory device 2200. For example, the data received from the host 1000 may be temporarily stored in the buffer memory 2170 until a program operation is completed. For example, the read data received from the memory device 2200 may be temporarily stored in the buffer memory 2170 until it is transmitted to the host 1000.

The buffer memory 2170 may be used as a storage which stores various types of information required for the operation of the memory controller 2100. The buffer memory 2170 may store a plurality of tables. For example, the buffer memory 2170 may store an address mapping table in which logical addresses and physical addresses are mapped to each other. For example, the buffer memory 2170 may store at least one of the first table and the second table.

FIG. 4 is a diagram illustrating an example of the memory controller illustrated in FIG. 1.

The memory controller 2100 may include a host interface 2110, a temperature information generator 2130, a memory interface 2140, a central processing unit (CPU) 2150, an error correction circuit 2160, and a buffer memory 2170.

The basic configurations and operations of the host interface 2110, the temperature information generator 2130, the memory interface 2140, the central processing unit 2150, the error correction circuit 2160, and the buffer memory 2170 are identical to those described with reference to FIG. 3.

A temperature sensor 2120b may be located outside the memory controller 2100. The temperature sensor 2120b may sense the temperature of the memory system 2000, and may provide a temperature sensing value St2 to the temperature information generator 2130. The configuration and operation of the temperature sensor 2120b are identical to those described with reference to the temperature sensor 2120a of FIG. 3.

Each of the memory controller 2100 and the memory device 2200 may be implemented as at least one chip. The chip(s), in which the memory controller 2100 and the memory device 2200 are implemented, and the temperature sensor 2120b may be mounted on a substrate. The temperature sensor 2120b may be positioned on the substrate spaced apart from the memory controller 2100.

The temperature information generator 2130 may convert the temperature sensing value St2 received from the temperature sensor 2120b into temperature information represented by a digital code, and may provide the temperature information to the memory interface 2140.

For example, when the temperature sensing value St2 is received from the temperature sensor 2120b, the temperature information generator 2130 may identify the temperature corresponding to the temperature sensing value St2 with reference to the first table, and may provide the identified temperature as the temperature information.

In an embodiment, when the temperature sensing value St2 is received from the temperature sensor 2120b, the temperature information generator 2130 may identify an index indicating a temperature interval corresponding to the temperature sensing value St2 with reference to the second table, and may output the identified index as the temperature information.

In an embodiment, the temperature information generator 2130 may periodically generate and update temperature information based on the temperature sensing value St2 received from the temperature sensor 2120b.

In an embodiment, the temperature information generator 2130 may provide the temperature information to the memory interface 2140 when a request is received from the central processing unit 2150.

FIG. 5 is a diagram illustrating an example of the memory interface illustrated in FIGS. 3 and 4.

The memory interface 2140 may include a command set expander 2140a, a transmission order determiner 2140b, a buffer 2140c, and a transmission controller 2140d.

The command set expander 2140a may generate an expanded command set by inserting temperature information into a command set that already includes a command and an address. Thus, the expanded command set may include the command, the address, and the temperature information. The command set may be received from the central processing unit 2150 illustrated in FIGS. 3 and 4, and the temperature information may be received from the temperature information generator 2130 illustrated in FIGS. 3 and 4.

The transmission order determiner 2140b may determine the order in which the command, the address, and the temperature information in the expanded command set are to be transmitted to the memory device 2200 (transmission order), and may queue the command, the address, and the temperature information in the buffer 2140c in the determined transmission order. The transmission order may be determined in accordance with a transmission policy.

In an embodiment, when a first transmission policy is used, the transmission order determiner 2140b may determine the transmission order so that, among the command, the address, and the temperature information included in the expanded command set, the temperature information is transmitted first. For example, the transmission order determiner 2140b may determine the transmission order to be the order of the temperature information-command-address.

In an embodiment, when a second transmission policy is used, the transmission order determiner 2140b may determine the transmission order so that, among the command, the address, and the temperature information included in the expanded command set, the temperature information is transmitted last. For example, the transmission order determiner 2140b may determine the transmission order to be the order of the command-address-temperature information.

When the transmission order determiner 2140b and the memory device 2200 share the policies on the input/output order of the expanded command set, the transmission order determiner 2140b may output the expanded command set in various manners, and thus embodiments of the present disclosure are not limited to the above-described first or second transmission policy.

The buffer 2140c may temporarily queue (or store) the command, the address, and the temperature information in the determined transmission order, and may sequentially output these items of the expanded command set from the queue under the control of the transmission controller 2140d.

The transmission controller 2140d may control the transmission of the expanded command set. The transmission controller 2140d may control the buffer 2140c so that the command, the address, and the temperature information in the expanded command set are transmitted to the memory device 2200 in the order in which they are queued in the buffer 2140c.

FIGS. 6 and 7 are diagrams explaining an example of generating temperature information.

The temperature information generator 2130 may convert a temperature sensing value St1 or St2, which is an analog signal, into digital code. For example, the temperature information generator 2130 may include an analog-to-digital converter (ADC).

In an embodiment, the temperature information generator 2130 may generate temperature corresponding to the temperature sensing value St1 or St2 as temperature information. For example, when the temperature sensing value St (St1 or St2) is 75° C., the temperature information generator 2130 may generate a binary number of ‘01001011’ indicating 75 as the temperature information, as illustrated in FIG. 6.

In an embodiment, the temperature information generator 2130 may generate, as the temperature information, an index indicating a temperature interval to which temperature corresponding to the temperature sensing value St1 or St2 belongs. For example, when the temperature sensing value corresponds to a temperature interval from 71° C. to 75° C., the temperature information generator 2130 may generate a binary number of ‘00010000’ indicating the temperature interval from 71° C. to 75° C. as the temperature information, as illustrated in FIG. 7.

FIG. 8 is a flowchart illustrating a method of operating a memory controller according to an embodiment of the present disclosure.

At step 801, the memory controller 2100 may generate a command set including a command and an address.

At step 803, the memory controller 2100 may generate temperature information.

At step 805, the memory controller 2100 may generate an expanded command set by inserting the temperature information into the command set.

At step 807, the memory controller 2100 may determine a transmission order in which the command, the address, and the temperature information in the expanded command set are to be output to the memory device 2200.

At step 809, the memory controller 2100 may transmit the expanded command set to the memory device 2200. Here, the memory controller 2100 may transmit the command, the address, and the temperature information in the expanded command set to the memory device 2200 in the transmission order determined at step 809.

FIG. 9 is a diagram illustrating an exemplary memory controller illustrated in FIG. 1.

The memory controller 2100 may include a host interface 2110, a temperature sensor 2120a, a temperature information generator 2130, a memory interface 2140, a central processing unit (CPU) 2150, an error correction circuit 2160, and a buffer memory 2170.

The basic configurations and operations of the host interface 2110, the error correction circuit 2160, and the buffer memory 2170 are identical to those described with reference to FIG. 3. The memory interface 2140 may communicate with the memory device 2200 using a set interface protocol.

The memory controller 2100 may include the temperature sensor 2120a, and the memory system 2000 may include a temperature sensor 2120b. The types and operations of the temperature sensors 2120a and 2120b are identical to those described with reference to FIGS. 3 and 4.

The temperature sensor 2120a may sense the temperature of the memory controller 2100 and provide a temperature sensing value St1 to the temperature information generator 2130, and the temperature sensor 2120b may sense the temperature of the memory system 2000 and provide a temperature sensing value St2 to the temperature information generator 2130.

The memory controller 2100 may be implemented as at least one chip. The temperature sensor 2120a may be located inside the chip in which the memory controller 2100 is implemented or located on the outer surface of the chip in which the memory controller 2100 is implemented.

Each of the memory controller 2100 and the memory device 2200 may be implemented as at least one chip. The temperature 2120b may be mounted on a substrate on which the chips in which the memory controller 2100 and the memory device 2200 are implemented are mounted. For example, the temperature sensor 2120b may be disposed on the substrate spaced apart from the memory controller 2100. In another example, the temperature sensor 2120b may be disposed on the substrate containing both the memory controller 2100 and the memory device 2100 spaced apart from each. For example, the temperature sensor 2120b may be interposed between the memory controller 2100 and the memory device 2200. In an embodiment, the distance between the temperature sensor 2120b and the memory device 2200 may be less than the distance between the temperature sensor 2120b and the memory controller 2100.

The temperature information generator 2130 may determine or identify (via a table) the temperature of the memory controller 2100 and the temperature of the memory system 2000 based on the temperature sensing values St1 and St2 received from the temperature sensors 2120a and 2120b.

In an embodiment, the temperature information generator 2130 may include a first table in which temperatures are mapped to respective temperature sensing values corresponding thereto. The temperature information generator 2130 may identify temperatures corresponding to the temperature sensing values St1 and St2 with reference to the first table.

In an embodiment, the temperature information generator 2130 may compare the temperature corresponding to the temperature sensing value St1 (indicative of the temperature of the memory controller 2100 and denoted the first temperature), with the temperature corresponding to the temperature sensing value St2 (indicative of the temperature of the memory system 2000 and denoted the second temperature). When the difference between these two temperatures is greater than a first threshold value, the temperature information generator 2130 may transmit a first signal indicating such a result to the central processing unit 2150. The first threshold value may be experimentally determined.

In an embodiment, whenever the temperature sensing values St1 and St2 are received, the temperature information generator 2130 may calculate the difference between the first temperature and the second temperature and store the calculated difference. The temperature information generator 2130 may compare a first difference calculated based on currently received temperature sensing values St1 and St2 with a second difference calculated based on previously received temperature sensing values St1 and St2. When the difference between the first difference and the second difference is greater than a second threshold value, the temperature information generator 2130 may transmit a second signal indicating such a result to the central processing unit 2150. The second threshold value may be experimentally determined.

When the difference between the first temperature and the second temperature is greater than the first threshold value or when the difference between the first difference and the second difference is greater than the second threshold value may indicate that the surrounding environment (e.g., temperature) of the memory system 2000 is rapidly changing.

When the first signal or the second signal is received from the temperature information generator 2130, the central processing unit 2150 may perform one or more set operations enabling the reliability of the memory system 2000 to be maintained. For example, the set operation may include controlling the speed of a fan associated with the memory system 2000 and/or sending a warning message to the host 1000, but embodiments of the present disclosure are not limited to these operations.

The central processing unit 2150 may perform various types of operations or generate a command set so as to control the memory device 2200. The command set may include a command and an address. For example, the central processing unit 2150 may generate a command set required for a program operation, a read operation or an erase operation in response to a request received from the host 1000, and may transmit the generated command set to the memory interface 2140.

FIG. 10 is a diagram illustrating a memory device according to an embodiment of the present disclosure.

The memory device 2200 may include a memory cell array 2210 which stores data, a peripheral circuit including components 2220, 2230, 2240, 2250, and 2260 (further described below), which performs a program operation, a read operation or an erase operation, and control logic 2270 which controls the peripheral circuit.

The memory cell array 2210 may include a plurality of memory blocks which store data. Each of the memory blocks may include a plurality of memory cells. The memory cells may be implemented in a two-dimensional (2D) structure in which the memory cells are horizontally arranged on a substrate or a three-dimensional (3D) structure in which the memory cells are vertically stacked on a substrate.

The peripheral circuit may include a voltage generator 2220, a row decoder 2230, a page buffer 2240, a column decoder 2250, and an input/output circuit 2260.

The voltage generator 2220 may generate operating voltages Vop required for various operations in response to an operation signal OPS. For example, the operating voltages Vop may include a program voltage, a read voltage, an erase voltage, and/or a pass voltage. When an incremental step pulse programming (ISPP) method is used in a program operation, the program voltage may include a program start voltage, a program step voltage, and/or a program verify voltage. In the ISPP method, one or more program loops may be performed. One program loop may include applying a program voltage and applying a program verify voltage. A program voltage applied in a first program loop, among program loops, may be referred to as the program start voltage, and the increment of the program voltage in each successive iteration of the program loop may be referred to as the program step voltage. The erase voltage may be a voltage applied to a bit line, a source line or a bulk during an erase operation.

The voltage generator 2220 may output the generated operating voltages Vop to the row decoder 2230.

The row decoder 2230 may transmit the operating voltages Vop to a memory block, selected by a row address RADD from among the memory blocks included in the memory cell array 2210, through local lines coupled to the selected memory block.

The page buffer 2240 may include a plurality of latches coupled to bit lines. The page buffer 2240 may temporarily store data in response to a control signal PBSIG during a program operation and a read operation.

The column decoder 2250 may transfer data received from the input/output circuit 2260 to the page buffer 2240 in response to a column address CADD during a program operation, or may transfer data received from the page buffer 2240 to the input/output circuit 2260 during a read operation.

The input/output circuit 2260 may be coupled to a memory controller (e.g., 2100 of FIGS. 3 and 4) through input/output lines included in a channel CHk and configured to input/output an expanded command set and data DATA, or may be coupled to a memory controller (e.g., 2100 of FIG. 9) and configured to input/output a command set and data DATA. The command set may include a command CMD and an address ADD. The expanded command set may include a command CMD, an address ADD, and temperature information Inf_temp. When a first transmission policy is used, the input/output circuit 2260 may determine that the expanded command set is received in the order of the temperature information Inf_temp-command CMD-address ADD. When a second transmission policy is used, the input/output circuit 2260 may determine that the expanded command set is received in the order of the command CMD-address ADD-temperature information Inf_temp.

For example, during a program operation, the input/output circuit 2260 may transmit the at least one of the command CMD, the address ADD, and the temperature information Inf_temp, received from the memory controller 2100, to the control logic 2270, and may transmit the data DATA to the column decoder 2250. The address ADD that is input to the input/output circuit 2260 may be a physical address output from the memory controller 2100. For example, during a read operation, the input/output circuit 2260 may output the data DATA, received from the column decoder 2250, to the memory controller 2100 through input/output lines.

The control logic 2270 may control the peripheral circuit and components thereof, i.e., 2220, 2230, 2240, 2250, and 2260, in response to at least one of the command CMD, the address ADD, and the temperature information Inf_temp, received through the input/output circuit 2260. The control logic 2270 may generate the operation signal OPS and the control signal PBSIG in response to the command CMD, and may generate the row address RADD and the column address CADD in response to the address ADD. The row address RADD may be output to the row decoder 2230, and the column address CADD may be output to the column decoder 2250.

The control logic 2270 may determine the level of each operating voltage Vop, and may control the voltage generator 2220 so that the level-determined operating voltage Vop is generated. In an embodiment, the control logic 2270 may determine the level of each operating voltage Vop based on the temperature information Inf_temp, and may control the voltage generator 2220 so that the level-determined operating voltage Vop is generated. For example, in spite of the operating voltage Vop that is used for the same operation, the control logic 2270 may determine the operating voltage Vop so that the operating voltage Vop has different levels depending on the temperature information Inf_temp. For example, in an embodiment, the control logic 2270 may determine the operating voltage Vop with reference to a third table in which operating voltages are mapped to pieces of temperature information corresponding thereto. The third table may be loaded from the memory cell array 2210.

FIG. 11 is a diagram explaining the third table.

In FIG. 11, an example in which indices indicating temperature intervals are used as temperature information is illustrated.

The third table may include indices indicating temperature intervals and read voltages Vrd1, Vrd2, and Vrd3 mapped to respective indices corresponding thereto. As described above with reference to FIG. 2, the read voltage Vrd1 may be used to distinguish an erased state E0 from a first program state P1, the read voltage Vrd2 may be used to distinguish the first program state P1 from a second program state P2, and the read voltage Vrd3 may be used to distinguish the second program state P2 from a third program state P3.

During a read operation, the control logic 2270 may control the voltage generator 2220 so that a read voltage having a voltage level corresponding to temperature information (i.e., the index) received from the memory controller 2100 is generated. For example, when the temperature information received from the memory controller 2100 is a digital code of ‘00010000’, the control logic 2270 may determine, from the table of FIG. 11, the first read voltage Vrd1 to be 5.1 V, the second read voltage Vrd2 to be 7.1 V, and the third read voltage Vrd3 to be 9.1 V, and may control the voltage generator 2220 to generate read voltages having these determined voltage levels.

Although an example in which the read voltages Vrd1, Vrd2, and Vrd3 are included in the third table is illustrated in FIG. 11, embodiments of the present disclosure are not limited thereto. For example, the third table may include temperature information and a program start voltage, a program verify voltage, a program step voltage, a read voltage, an erase voltage, and/or a pass voltage that correspond to the temperature information.

FIG. 12 is a diagram illustrating an exemplary memory block.

A memory cell array may include a plurality of memory blocks, and a representative memory block BLKi of the plurality of memory blocks is illustrated in FIG. 12 by way of example.

A plurality of word lines arranged in parallel to each other between a first select line and a second select line may be coupled to the memory block BLKi. Here, the first select line may be a source select line SSL, and the second select line may be a drain select line DSL. In detail, the memory block BLKi may include a plurality of strings ST coupled between bit lines BL1 to BLm and a source line SL. The bit lines BL1 to BLm may be coupled to the strings ST, respectively, and the source line SL may be coupled in common to the strings ST. The strings ST may be equally configured, and thus the string ST coupled to the first bit line BL1 will be described in detail by way of example.

The string ST may include a source select transistor SST, a plurality of memory cells F1 to F16, and a drain select transistor DST which are coupled in series to each other between the source line SL and the first bit line BL1. A single string ST may include at least one source select transistor SST and at least one drain select transistor DST, and more than sixteen memory cells, i.e., F1 to F16, illustrated in the drawing may be included in the string ST.

A source of the source select transistor SST may be coupled to the source line SL, and a drain of the drain select transistor DST may be coupled to the first bit line BL1. The memory cells F1 to F16 may be coupled in series between the source select transistor SST and the drain select transistor DST. Gates of the source select transistors SST included in different strings ST may be coupled to the source select line SSL, gates of the drain select transistors DST included in different strings ST may be coupled to the drain select line DSL, and gates of the memory cells F1 to F16 may be coupled to a plurality of word lines WL1 to WL16, respectively. A group of memory cells coupled to the same word line, among the memory cells included in different strings ST, may be referred to as a ‘physical page (PPG)’. Therefore, the memory block BLKi may include the same number of physical pages (PPG) as word lines WL1 to WL16.

When the memory block BLKi is a single-level cell (SLC) block which operates in an SLC mode, each of physical pages included in the memory block BLKi may store data corresponding to one logical page. The data corresponding to one logical page may include the same number of data bits as memory cells in one physical page.

When the memory block BLKi is an m-bit multi-level cell (MLC) block which operates in an m-bit MLC mode, each of physical pages included in the memory block BLKi may store data corresponding to m logical pages.

FIG. 13 is a diagram illustrating an embodiment of a memory system including the memory controller illustrated in FIGS. 3, 4, and/or 9.

A memory system 30000 may be implemented as a cellular phone, a smartphone, a tablet, a personal computer (PC), a personal digital assistant (PDA) or a wireless communication device. The memory system 30000 may include a memory device 2200 and a memory controller 2100 which controls the operation of the memory device 2200.

The memory controller 2100 may control a data access operation of the memory device 2200, for example, a program operation, an erase operation or a read operation, under the control of a processor 3100.

Data programmed to the memory device 2200 may be output via a display 3200 under the control of the memory controller 2100.

A radio transceiver 3300 may exchange radio signals through an antenna ANT. For example, the radio transceiver 3300 may convert radio signals received through the antenna ANT into signals that may be processed by the processor 3100. Therefore, the processor 3100 may process the signals output from the radio transceiver 3300, and may transmit the processed signals to the memory controller 2100 or the display 3200. The memory controller 2100 may transmit the signals processed by the processor 3100 to the memory device 2200. Further, the radio transceiver 3300 may convert signals output from the processor 3100 into radio signals, and output the radio signals to an external device through the antenna ANT. An input device 3400 may be a device that is capable of inputting a control signal for controlling the operation of the processor 3100 or data to be processed by the processor 3100. The input device 3400 may be implemented as a pointing device such as a touch pad or a computer mouse, a keypad or a keyboard. The processor 3100 may control the operation of the display 3200 so that data output from the memory controller 2100, data output from the radio transceiver 3300, or data output from the input device 3400 is output via the display 3200.

In accordance with an embodiment, the memory controller 2100 that is capable of controlling the operation of the memory device 2200 may be implemented as a part of the processor 3100 or as a chip provided separately from the processor 3100.

FIG. 14 is a diagram illustrating an embodiment of a memory system including the memory controller illustrated in FIGS. 3, 4, and/or 9.

A memory system 40000 may be embodied in a personal computer (PC), a tablet, a net-book, an e-reader, a personal digital assistant (PDA), a portable multimedia player (PMP), an MP3 player, or an MP4 player.

The memory system 40000 may include a memory device 2200 and a memory controller 2100 which controls a data processing operation of the memory device 2200.

Further, a processor 4100 may output data, stored in the memory device 2200, via a display 4300 according to data input through an input device 4200. For example, the input device 4200 may be implemented as a pointing device such as a touch pad or a computer mouse, a keypad or a keyboard.

The processor 4100 may control the overall operation of the memory system 40000, and may control the operation of the memory controller 2100. In an embodiment, the memory controller 2100 that is capable of controlling the operation of the memory device 2200 may be implemented as a part of the processor 4100 or as a chip provided separately from the processor 4100.

FIG. 15 is a diagram illustrating an embodiment of a memory system including the memory controller illustrated in FIGS. 3, 4, and/or 9.

A memory system 50000 may be embodied in an image processing device, for example, a digital camera, a cellular phone provided with a digital camera, a smartphone provided with a digital camera, or a tablet provided with a digital camera.

The memory system 50000 may include a memory device 2200 and a memory controller 2100 which may control a data processing operation of the memory device 2200, for example, a program operation, an erase operation or a read operation.

An image sensor 5200 may convert an optical image into digital signals, and the digital signals may be transmitted to a processor 5100 or the memory controller 2100. Under the control of the processor 5100, the digital signals may be output via a display 5300, or may be stored in the memory device 2200 through the memory controller 2100.

Data stored in the memory device 2200 may be output via the display 5300 under the control of the processor 5100 or the memory controller 2100.

In an embodiment, the memory controller 2100 that is capable of controlling the operation of the memory device 2200 may be implemented as a part of the processor 5100 or as a chip provided separately from the processor 5100.

FIG. 16 is a diagram illustrating an embodiment of a memory system including the memory controller illustrated in FIGS. 3, 4, and/or 9.

A memory system 70000 may be implemented as a memory card or a smart card. The memory system 70000 may include a memory device 2200, a memory controller 2100, and a card interface 7100.

The memory controller 2100 may control data exchange between the memory device 2200 and the card interface 7100. In an embodiment, the card interface 7100 may be, but is not limited to, a secure digital (SD) card interface or a multi-media card (MMC) interface.

The card interface 7100 may interface data exchange between a host 60000 and the memory controller 2100 according to the protocol of the host 60000. In an embodiment, the card interface 7100 may support a universal serial bus (USB) protocol and an interchip (IC)-USB protocol. Here, the card interface 7100 may refer to hardware capable of supporting a protocol which is used by the host 60000, software installed in the hardware, or a signal transmission method performed by the hardware.

When the memory system 70000 is coupled to a host interface 6200 of the host 60000, such as a PC, a tablet, a digital camera, a digital audio player, a cellular phone, console video game hardware or a digital set-top box, the host interface 6200 may perform data communication with the memory device 2200 through the card interface 7100 and the memory controller 2100 under the control of a microprocessor 6100.

In accordance with embodiments of the present disclosure, the size of a memory system may be decreased, and the reliability of temperature information of the memory system may be improved.

While various embodiments of the present invention have been illustrated and described, it will be understood by those skilled in the art in light of the present disclosure that the disclosed embodiments are examples only. Accordingly, the present invention is not limited to or by any of the disclosed embodiments. Rather, the present invention encompasses all modifications and variations of any of the disclosed embodiments to the extent such modifications and variations fall within the scope of the claims.

What is claimed is:

1. A memory controller, comprising:
a central processing unit configured to generate a command set that includes a command and an address for controlling an operation of a memory device;
a temperature information generator configured to generate temperature information based on a temperature sensing value; and
a memory interface configured to generate an expanded command set by including the temperature information in the command set, and transmit the expanded command set to the memory device.

2. The memory controller according to claim 1, wherein the central processing unit is further configured to request the temperature information generator to generate the temperature information and transmit the temperature information to the memory interface.

3. The memory controller according to claim 1, wherein the memory interface comprises:
a buffer; and
a transmission order determiner configured to determine a transmission order in which the command, the address, and the temperature information in the expanded command set are to be transmitted to the memory device, and to queue the command, the address, and the temperature information in the expanded command set in the buffer in the determined transmission order.

4. The memory controller according to claim 3, wherein the transmission order determiner determines the transmission order so that the temperature information is to be transmitted prior to the command and the address or so that the temperature information is to be transmitted subsequent to the command and the address.

5. The memory controller according to claim 3, wherein the memory interface further comprises: a transmission controller configured to control the buffer so that the command, the address, and the temperature information in the expanded command set are sequentially transmitted to the memory device in an order in which the command, the address, and the temperature information are queued in the buffer.

6. The memory controller according to claim 1, wherein the temperature information generator is further configured to receive the temperature sensing value from a temperature sensor that is disposed inside the memory controller.

7. The memory controller according to claim 1, wherein the temperature information generator is further configured to receive the temperature sensing value from a temperature sensor that is disposed externally to the memory controller and the memory device.

8. The memory controller according to claim 1, wherein the temperature information generator generates a temperature corresponding to the temperature sensing value as the temperature information.

9. The memory controller according to claim 1, wherein the temperature information generator generates, as the temperature information, an index indicating a temperature interval corresponding to the temperature sensing value, among a plurality of set temperature intervals.

10. A memory system, comprising:
a memory controller configured to generate an expanded command set including a command, an address, and temperature information; and
a memory device configured to receive the expanded command set from the memory controller, perform an operation in response to the command and the address in the expanded command set, and determine operating voltages to be used for the operation based on the temperature information in the expanded command set.

11. The memory system according to claim 10, wherein the operating voltages comprise at least one of a program start voltage, a program verify voltage, a program step voltage, a read voltage, an erase voltage, and a pass voltage.

12. A memory controller, comprising:
a temperature information generator configured to compare a first temperature corresponding to a first temperature sensing value with a second temperature corresponding to a second temperature sensing value, and to output a first signal when a difference between the first temperature and the second temperature is equal to or greater than a first threshold value; and
a central processing unit configured to perform a set operation when the first signal is received from the temperature information generator,
wherein the first temperature sensing value is indicative of temperature inside the memory controller, and the second temperature sensing value is indicative of temperature outside the memory controller.

13. The memory controller according to claim 12, wherein the set operation comprises: at least one of controlling a speed of a fan and sending a warning message to a host.
